(19) United States
(12) Patent Application Publication
(10) Pub. No.: US 2024/0192417 A1
(43) Pub. Date: Jun. 13, 2024

(54) LIQUID CRYSTAL OPTICAL ELEMENT

(71) Applicants: Japan Display Inc., Tokyo (JP); OSAKA UNIVERSITY, Osaka (JP)

(72) Inventors: Koichi IGETA, Tokyo (JP); Yasushi TOMIOKA, Tokyo (JP); Shinichiro OKA, Tokyo (JP); Junji KOBASHI, Tokyo (JP); Hiroyuki YOSHIDA, Suita-shi (JP)

(73) Assignees: Japan Display Inc., Tokyo (JP); OSAKA UNIVERSITY, Osaka (JP)

(21) Appl. No.: 18/431,331

(22) Filed: Feb. 2, 2024

Related U.S. Application Data
(63) Continuation of application No. PCT/JP2022/021571, filed on May 26, 2022.

(30) Foreign Application Priority Data
Aug. 4, 2021 (JP) 2021-128318

(51) Int. Cl. G02B 5/30

(52) U.S. Cl. CPC G02B 5/3016

(57) ABSTRACT

According to one embodiment, a liquid crystal optical element includes an optical waveguide including a first main surface and a second main surface opposed to the first main surface, an alignment film disposed on the second main surface, a liquid crystal layer which overlaps the alignment film, which includes cholesteric liquid crystals, and which reflects at least part of light incident through the optical waveguide toward the optical waveguide, and a transparent first cover member opposed to the liquid crystal layer with a first low-refractive-index layer interposed between the first cover member and the liquid crystal layer, the first low-refractive-index layer having a refractive index lower than a refractive index of the liquid crystal layer.

### CROSS-REFERENCE TO RELATED APPLICATIONS

This application is a Continuation application of PCT Application No. PCT/JP2022/021571, filed May 26, 2022 and based upon and claiming the benefit of priority from Japanese Patent Application No. 2021-128318, filed Aug. 4, 2021, the entire contents of all of which are incorporated herein by reference.

### FIELD

Embodiments described herein relate generally to a liquid crystal optical element.

### BACKGROUND

For example, liquid crystal polarization gratings for which liquid crystal materials are used have been proposed. Such a liquid crystal polarization grating divides incident light into zero-order diffracted light and first-order diffracted light, when light of a wavelength λ is incident thereon. In optical elements for which liquid crystal materials are used, it is necessary to adjust parameters such as the refractive anisotropy Δn of a liquid crystal layer (difference between the refractive index ne for extraordinary light and the refractive index no for ordinary light of the liquid crystal layer) and the thickness d of the liquid crystal layer, as well as the grating period.

### BRIEF DESCRIPTION OF THE DRAWINGS

FIG. 1 is a cross-sectional view schematically illustrating a liquid crystal optical element 100 according to Embodiment 1.

FIG. 2 is a cross-sectional view schematically illustrating the structure of a liquid crystal layer 3.

FIG. 3 is a plan view schematically illustrating the liquid crystal optical element 100.

FIG. 4 is a cross-sectional view schematically illustrating a modified example of the liquid crystal optical element 100 according to Embodiment 1.

FIG. 5 is a cross-sectional view schematically illustrating a liquid crystal optical element 100 according to Embodiment 2.

FIG. 6 is a cross-sectional view schematically illustrating a liquid crystal optical element 100 according to Embodiment 3.

FIG. 7 is a cross-sectional view schematically illustrating a liquid crystal optical element 100 according to Embodiment 4.

FIG. 8 is a cross-sectional view schematically illustrating a liquid crystal optical element 100 according to Embodiment 5.

FIG. 9 is a cross-sectional view schematically illustrating a liquid crystal optical element 100 according to Embodiment 6.

FIG. 10 is a cross-sectional view schematically illustrating a liquid crystal optical element 100 according to Embodiment 7.

FIG. 11 is a diagram illustrating an example of the outside of a photovoltaic cell device 200.

FIG. 12 is a diagram for explaining the operation of the photovoltaic cell device 200 illustrated in FIG. 11.

FIG. 13 is a diagram illustrating another example of the outside of the photovoltaic cell device 200.

FIG. 14 is a cross-sectional view of the photovoltaic cell device 200 illustrated in FIG. 13.

### DETAILED DESCRIPTION

Embodiments described herein aim to provide a liquid crystal optical element which can suppress the decrease in the efficiency of light utilization.

In general, according to one embodiment, a liquid crystal optical element comprises an optical waveguide comprising a first main surface and a second main surface opposed to the first main surface, an alignment film disposed on the second main surface, a liquid crystal layer which overlaps the alignment film, which comprises cholesteric liquid crystals, and which reflects at least part of light incident through the optical waveguide toward the optical waveguide, and a transparent first cover member opposed to the liquid crystal layer with a first low-refractive-index layer interposed between the first cover member and the liquid crystal layer, the first low-refractive-index layer having a refractive index lower than a refractive index of the liquid crystal layer.

According to the embodiments, a liquid crystal optical element which can suppress the decrease in the efficiency of light utilization can be provided.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

In the drawings, an X-axis, a Y-axis, and a Z-axis orthogonal to each other are described to facilitate understanding as necessary. A direction along the Z-axis is referred to as a Z direction or a first direction A1, a direction along the Y-axis is referred to as a Y direction or a second direction A2, and a direction along the X-axis is referred to as an X direction or a third direction A3. A plane defined by the X-axis and the Y-axis is referred to as an X-Y plane, a plane defined by the X-axis and the Z-axis is referred to as an X-Z plane, and a plane defined by the Y-axis and the Z-axis is referred to as a Y-Z plane.

### Embodiment 1

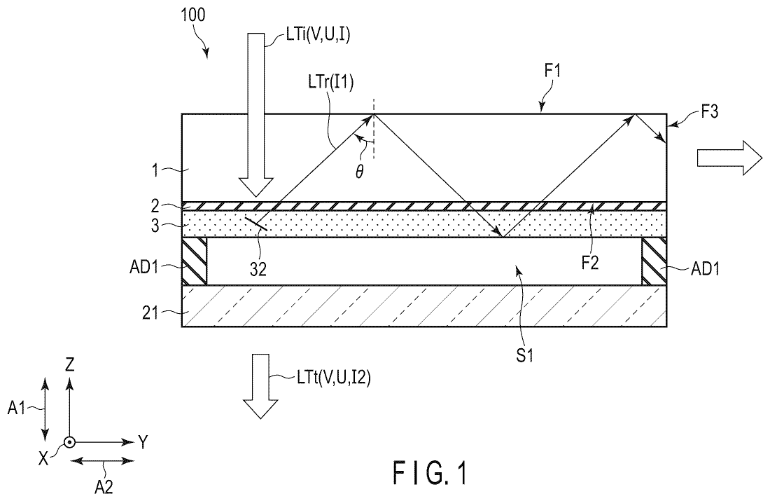

FIG. 1 is a cross-sectional view schematically illustrating a liquid crystal optical element 100 according to Embodiment 1.

The liquid crystal optical element 100 comprises an optical waveguide 1, an alignment film 2, a liquid crystal layer 3, a first cover member 21, and a first adhesive AD1.

The optical waveguide 1 is composed of a transparent member that transmits light, for example, a transparent glass plate or a transparent synthetic resin plate. The optical waveguide 1 may be composed of, for example, a transparent synthetic resin plate having flexibility. The optical waveguide 1 can assume an arbitrary shape. For example, the optical waveguide 1 may be curved. The refractive index of the optical waveguide 1 is greater than, for example, the refractive index of air. The optical waveguide 1 functions as, for example, a windowpane.

In the present specification, “light” includes visible light and invisible light. For example, the wavelength of the lower limit of the visible light range is greater than or equal to 360 nm but less than or equal to 400 nm, and the wavelength of the upper limit of the visible light range is greater than or equal to 760 nm but less than or equal to 830 nm. Visible light includes a first component (blue component) of a first wavelength band (for example, 400 nm to 500 nm), a second component (green component) of a second wavelength band (for example, 500 nm to 600 nm), and a third component (red component) of a third wavelength band (for example, 600 nm to 700 nm). Invisible light includes ultraviolet rays of a wavelength band shorter than the first wavelength band and infrared rays of a wavelength band longer than the third wavelength band.

In the present specification, to be “transparent” should preferably be to be colorless and transparent. Note that to be “transparent” may be to be translucent or to be colored and transparent.

The optical waveguide 1 is formed in the shape of a flat plate along the X-Y plane, and comprises a first main surface F1, a second main surface F2, and a side surface F3. The first main surface F1 and the second main surface F2 are surfaces substantially parallel to the X-Y plane and are opposed to each other in the first direction A1. The side surface F3 is a surface extending in the first direction A1. In the example illustrated in FIG. 1, the side surface F3 is a surface substantially parallel to the X-Z plane, but the side surface F3 includes a surface substantially parallel to the Y-Z plane.

The alignment film 2 is disposed on the second main surface F2. The alignment film 2 is a horizontal alignment film having alignment restriction force along the X-Y plane. The alignment film 2 is formed of a transparent material, for example, polyimide.

The liquid crystal layer 3 overlaps the alignment film 2 in the first direction A1. That is, the alignment film 2 is located between the optical waveguide 1 and the liquid crystal layer 3, and contacts the optical waveguide 1 and the liquid crystal layer 3. The liquid crystal layer 3 reflects at least part of light LTi incident from the first main surface F1 side toward the optical waveguide 1. For example, the liquid crystal layer 3 comprises cholesteric liquid crystals which reflect at least one of first circularly polarized light and second circularly polarized light that is circularly polarized in the opposite direction to that of first circularly polarized light, of light LTi incident through the optical waveguide 1. While the cholesteric liquid crystals will be described in detail later, a cholesteric liquid crystal turning in one direction forms a reflective surface 32 which reflects circularly polarized light corresponding to its turning direction, of light of a specific wavelength.

First circularly polarized light and second circularly polarized light reflected by the liquid crystal layer 3 are, for example, infrared rays, but may be visible light or ultraviolet rays. In the present specification, ‘reflection’ in the liquid crystal layer 3 involves diffraction inside the liquid crystal layer 3.

The first cover member 21 is opposed to the liquid crystal layer 3 in the first direction A1. The first cover member 21 is separated from the liquid crystal layer 3. A first low-refractive-index layer S1 is interposed between the liquid crystal layer 3 and the first cover member 21. The first low-refractive-index layer S1 has a refractive index lower than those of the liquid crystal layer 3 and the first cover member 21. The first low-refractive-index layer S1 is, for example, a vacuum (refractive index; 1.0) or an air layer (refractive index; approximately 1.0).

The first cover member 21 is a transparent flat plate and is formed of, for example, inorganic glass or transparent resin.

As the inorganic glass, soda-lime glass (refractive index; approximately 1.52) or borosilicate glass (refractive index; approximately 1.47) can be applied, for example.

As the transparent resin, acrylic resin (refractive index; 1.49 to 1.53), polyethylene terephthalate (refractive index; approximately 1.60), polycarbonate (refractive index; approximately 1.59), or polyvinyl chloride (refractive index; approximately 1.54) can be applied, for example.

The thickness of the first cover member 21 is 0.1 mm to 25 mm and should preferably be 1 mm to 20 mm.

The first adhesive AD1 adheres the periphery of the first cover member 21 to the liquid crystal layer 3 in a state in which the first low-refractive-index layer S1 is interposed between the liquid crystal layer 3 and the first cover member 21. The first adhesive AD1 is formed in, for example, the shape of a continuous loop and seals the air layer as the first low-refractive-index layer S1 on its inside.

As the first adhesive AD1, a chemically reactive adhesive, such as epoxy resin, acrylic resin, urethane resin, or modified silicone resin, can be applied, for example. In addition, as other examples of the first adhesive AD1, an aqueous adhesive, a solvent-based adhesive, a hot-melt adhesive, or the like also can be applied.

The optical action of the liquid crystal optical element 100 in Embodiment 1 illustrated in FIG. 1 will be described next.

Light LTi incident on the liquid crystal optical element 100 includes, for example, visible light V, ultraviolet rays U, and infrared rays I.

In the example illustrated in FIG. 1, to facilitate understanding, it is assumed that light LTi is incident substantially perpendicularly to the optical waveguide 1. The angle of incidence of light LTi to the optical waveguide 1 is not particularly limited. For example, light LTi may be incident on the optical waveguide 1 at angles of incidence different from each other.

Light LTi enters the inside of the optical waveguide 1 from the first main surface F1, is emitted from the second main surface F2, is transmitted through the alignment film 2, and is incident on the liquid crystal layer 3. Then, the liquid crystal layer 3 reflects light LTr, which is part of light LTi, toward the optical waveguide 1, and transmits other light LTt. Here, any optical loss such as absorption in the optical waveguide 1 and the liquid crystal layer 3 is ignored.

Light LTr reflected by the liquid crystal layer 3 is, for example, first circularly polarized light of a predetermined wavelength. In addition, light LTt transmitted through the liquid crystal layer 3 includes second circularly polarized light of the predetermined wavelength and light of a wavelength different from the predetermined wavelength. The predetermined wavelength here is, for example, the wavelength of infrared rays I, and light LTr reflected by the liquid crystal layer 3 is first circularly polarized light I1 of infrared rays I. Light LTt transmitted through the liquid crystal layer 3 includes visible light V, ultraviolet rays U, and second circularly polarized light 12 of infrared rays I. In the present specification, circularly polarized light may be precise circularly polarized light or may be circularly polarized light approximate to elliptically polarized light.

The liquid crystal layer 3 reflects first circularly polarized light I1 toward the optical waveguide 1 at an angle θ of entry which satisfies the optical waveguide conditions in the optical waveguide 1. The angle θ of entry here corresponds to an angle greater than or equal to the critical angle θc which causes total reflection at the interface between the optical waveguide 1 and the air. The angle θ of entry represents an angle to a perpendicular line orthogonal to the optical waveguide 1.

If the optical waveguide 1, the alignment film 2, and the liquid crystal layer 3 have equivalent refractive indices, the stacked layer body of these can be a single optical waveguide body. In this case, light LTr is guided toward the side surface F3 while being reflected repeatedly at the interface between the optical waveguide 1 and the air and the interface between the liquid crystal layer 3 and the first low-refractive-index layer (for example, air layer) S1.

According to Embodiment 1 as described above, since the liquid crystal layer 3 is protected by the first cover member 21, the adhesion of dirt or a waterdrop to the liquid crystal layer 3 is suppressed and the damage to the liquid crystal layer 3 is suppressed. This suppresses the undesirable scattering of light due to the adhesion of dirt or a waterdrop to the liquid crystal layer 3 or the undesirable scattering of light due to the damage to the liquid crystal layer 3, and further suppresses the decrease in the reflectance of the liquid crystal layer 3. Accordingly, the decrease in the efficiency of light utilization in the liquid crystal optical element 100 is suppressed.

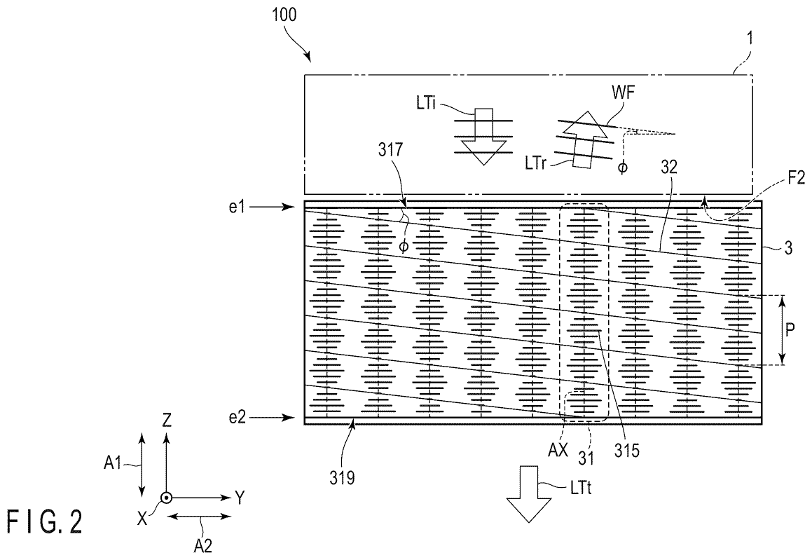

FIG. 2 is a cross-sectional view schematically illustrating the structure of the liquid crystal layer 3.

The optical waveguide 1 is indicated by a long dashed and double-short dashed line. In addition, the illustration of the alignment film and the first cover member illustrated in FIG. 1 is omitted.

The liquid crystal layer 3 comprises cholesteric liquid crystals 31 as helical structures. Each of the cholesteric liquid crystals 31 has a helical axis AX substantially parallel to the first direction A1. The helical axis AX is substantially perpendicular to the second main surface F2 of the optical waveguide 1.

Each of the cholesteric liquid crystals 31 has a helical pitch P in the first direction A1. The helical pitch P indicates one cycle (360 degrees) of the helix. The helical pitch P is constant with hardly any change in the first direction A1. Each of the cholesteric liquid crystals 31 includes liquid crystal molecules 315. The liquid crystal molecules 315 are stacked helically in the first direction A1 while turning.

The liquid crystal layer 3 comprises a first boundary surface 317 opposed to the second main surface F2 in the first direction A1, a second boundary surface 319 on the opposite side to the first boundary surface 317, and reflective surfaces 32 between the first boundary surface 317 and the second boundary surface 319. The first boundary surface 317 is a surface through which light LTi transmitted through the optical waveguide 1 enters the liquid crystal layer 3. Each of the first boundary surface 317 and the second boundary surface 319 is substantially perpendicular to the helical axis AX of the cholesteric liquid crystals 31. Each of the first boundary surface 317 and the second boundary surface 319 is substantially parallel to the optical waveguide 1 (or the second main surface F2)

The first boundary surface 317 includes liquid crystal molecules 315 located at one end e1 of both ends of the cholesteric liquid crystals 31. The first boundary surface 317 corresponds to a boundary surface between the alignment film not illustrated in the figure and the liquid crystal layer 3.

The second boundary surface 319 includes liquid crystal molecules 315 located at the other end e2 of both ends of the cholesteric liquid crystals 31. The second boundary surface 319 corresponds to a boundary surface between the liquid crystal layer 3 and the first low-refractive-index layer not illustrated in the figure.

In the example illustrated in FIG. 2, the reflective surfaces 32 are substantially parallel to each other. The reflective surfaces 32 are inclined with respect to the first boundary surface 317 and the optical waveguide 1 (or the second main surface F2), and have a substantially planar shape extending in one direction. The reflective surfaces 32 selectively reflect light LTr, which is part of light LTi incident through the first boundary surface 317, in accordance with Bragg's law. Specifically, the reflective surfaces 32 reflect light LTr such that the wave front WF of light LTr becomes substantially parallel to the reflective surfaces 32. More specifically, the reflective surfaces 32 reflect light LTr in accordance with the angle φ of inclination of the reflective surfaces 32 with respect to the first boundary surface 317.

The reflective surfaces 32 can be defined as follows. That is, the refractive index for light (for example, circularly polarized light) of a predetermined wavelength selectively reflected in the liquid crystal layer 3 changes gradually as the light travels through the inside of the liquid crystal layer 3. Thus, Fresnel reflection occurs gradually in the liquid crystal layer 3. In addition, Fresnel reflection occurs most strongly at the position where the refractive index for light changes most greatly in the cholesteric liquid crystals 31. That is, the reflective surfaces 32 correspond to the surfaces where Fresnel reflection occurs most strongly in the liquid crystal layer 3.

The alignment directions of the respective liquid crystal molecules 315 of cholesteric liquid crystals 31 adjacent to each other in the second direction A2 of the cholesteric liquid crystals 31 are different from each other. In addition, the respective spatial phases of cholesteric liquid crystals 31 adjacent to each other in the second direction A2 of the cholesteric liquid crystals 31 are different from each other. The reflective surfaces 32 correspond to the surfaces formed by the liquid crystal molecules 315 whose alignment directions are the same, or the surfaces along which the spatial phases are the same (equiphase wave surfaces). That is, each of the reflective surfaces 32 is inclined with respect to the first boundary surface 317 or the optical waveguide 1.

The shape of the reflective surfaces 32 is not limited to a planar shape as illustrated in FIG. 2, but may be a curved surface such as a concave shape or a convex shape and is not particularly limited. In addition, part of the reflective surfaces 32 may have irregularities, or the angles φ of inclination of the reflective surfaces 32 may not be uniform, or the reflective surfaces 32 may not be arranged regularly. According to the spatial phase distribution of the cholesteric liquid crystals 31, the reflective surfaces 32 having an arbitrary shape can be formed.

FIG. 2 illustrates the liquid crystal molecules 315 aligned in the average alignment directions as representatives of the liquid crystal molecules 315 located in the X-Y plane, for simplification of the drawing.

The cholesteric liquid crystals 31 reflect circularly polarized light of the same turning direction as that of the cholesteric liquid crystals 31, of light of a predetermined wavelength λ included in a selective reflection band Δλ. For example, if the turning direction of the cholesteric liquid crystals 31 is right-handed, they reflect right-handed circularly polarized light and transmit left-handed circularly polarized light, of light of the predetermined wavelength λ. Similarly, if the turning direction of the cholesteric liquid crystals 31 is left-handed, they reflect left-handed circularly polarized light and transmit right-handed circularly polarized light, of light of the predetermined wavelength λ.

The selective reflection band Δλ of the cholesteric liquid crystals 31 for perpendicularly incident light is generally expressed as “no*P to ne*P”, where P represents the helical pitch of the cholesteric liquid crystals 31, ne represents the refractive index for extraordinary light of the liquid crystal molecules 315, and no represents the refractive index for ordinary light of the liquid crystal molecules 315. Specifically, the selective reflection band Δλ of the cholesteric liquid crystals 31 varies in the range of “no*P to ne*P” according to the angle φ of inclination of the reflective surfaces 32, the angle of incidence on the first boundary surface 317, etc.

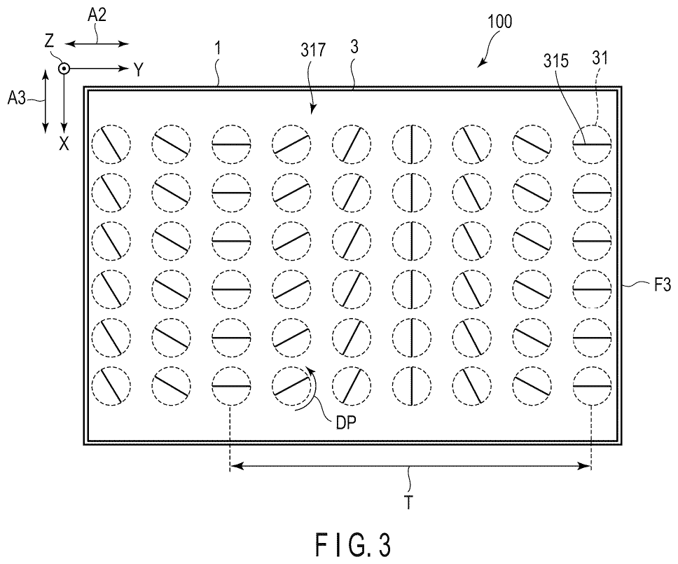

FIG. 3 is a plan view schematically illustrating the liquid crystal optical element 100.

FIG. 3 illustrates an example of the spatial phases of the cholesteric liquid crystals 31. The spatial phases here are illustrated as the alignment directions of the liquid crystal molecules 315 located in the first boundary surface 317 of the liquid crystal molecules 315 included in the cholesteric liquid crystals 31.

As for the cholesteric liquid crystals 31 arranged in the second direction A2, the alignment directions of the liquid crystal molecules 315 located in the first boundary surface 317 are different from each other. That is, the spatial phases of the cholesteric liquid crystals 31 in the first boundary surface 317 are different in the second direction A2.

In contrast, as for the cholesteric liquid crystals 31 arranged in the third direction A3, the alignment directions of the liquid crystal molecules 315 located in the first boundary surface 317 are substantially identical. That is, the spatial phases of the cholesteric liquid crystals 31 in the first boundary surface 317 are substantially identical in the third direction A3.

In particular, as for the cholesteric liquid crystals 31 arranged in the second direction A2, the respective alignment directions of the liquid crystal molecules 315 differ by equal angles. That is, in the first boundary surface 317, the alignment directions of the liquid crystal molecules 315 arranged in the second direction A2 change linearly. Accordingly, the spatial phases of the cholesteric liquid crystals 31 arranged in the second direction A2 change linearly in the second direction A2. As a result, the reflective surfaces 32 inclined with respect to the first boundary surface 317 and the optical waveguide 1 are formed as in the liquid crystal layer 3 illustrated in FIG. 2. The phrase ‘linearly change’ here means, for example, that the amount of change of the alignment directions of the liquid crystal molecules 315 is represented by a linear function. The alignment directions of the liquid crystal molecules 315 here correspond to the directions of the major axes of the liquid crystal molecules 315 in the X-Y plane. The alignment directions of the liquid crystal molecules 315 as described above are controlled by the alignment treatment performed for the alignment film 2.

Here, as illustrated in FIG. 3, in the first boundary surface 317, the interval between two cholesteric liquid crystals 31 between which the alignment directions of the liquid crystal molecules 315 change by 180 degrees in the second direction A2 is defined as a cycle T of the cholesteric liquid crystals 31. In FIG. 3, DP denotes the turning direction of the liquid crystal molecules 315. The angle φ of inclination of the reflective surfaces 32 illustrated in FIG. 2 is set as appropriate by the cycle T and the helical pitch P.

The liquid crystal layer 3 is formed in the following manner. For example, the liquid crystal layer 3 is formed by applying a liquid crystal material to the alignment film 2, which has been subjected to predetermined alignment treatment, and then irradiating the liquid crystal molecules 315 with light and polymerizing the liquid crystal molecules 315. Alternatively, the liquid crystal layer 3 is formed by controlling the alignment of a polymeric liquid crystal material that exhibits a liquid crystalline state at a predetermined temperature or a predetermined concentration to form the cholesteric liquid crystals 31 and then causing them to transition to a solid while maintaining the alignment.

In the liquid crystal layer 3, the cholesteric liquid crystals 31 adjacent to each other are coupled to each other while maintaining the alignment of the cholesteric liquid crystals 31, that is, while maintaining the spatial phases of the cholesteric liquid crystals 31, by polymerization or transition to a solid. As a result, in the liquid crystal layer 3, the respective alignment directions of the liquid crystal molecules 315 are fixed.

For example, a case where the helical pitch P of the cholesteric liquid crystals 31 is adjusted to set the selective reflection band Δλ to the wavelength band of infrared rays will be described. In order to increase the reflectance at the reflective surfaces 32 of the liquid crystal layer 3, it is desirable that the thickness in the first direction A1 of the liquid crystal layer 3 be set to approximately several times to ten times the helical pitch P. That is, the thickness of the liquid crystal layer 3 is approximately 1 to 10 μm and should preferably be 2 to 7 μm.

### Modified Example

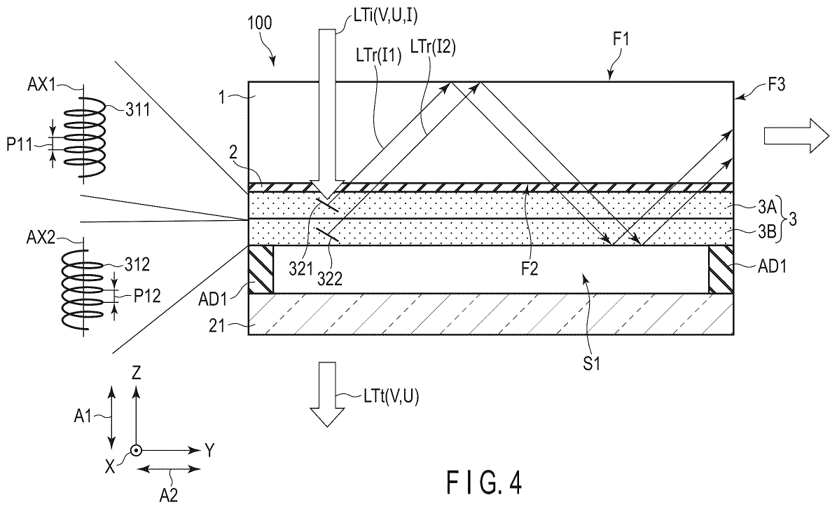

FIG. 4 is a cross-sectional view schematically illustrating a modified example of the liquid crystal optical element 100 according to Embodiment 1. The example illustrated in FIG. 4 is different from the example illustrated in FIG. 1 in that the liquid crystal layer 3 comprises a first layer 3A comprising a cholesteric liquid crystal 311 turning in a first turning direction and a second layer 3B comprising a cholesteric liquid crystal 312 turning in a second turning direction opposite to the first turning direction. The first layer 3A and the second layer 3B overlap in the first direction A1. The first layer 3A is located between the alignment film 2 and the second layer 3B, and the second layer 3B is located between the first layer 3A and the first low-refractive-index layer S1.

The cholesteric liquid crystal 311 included in the first layer 3A is configured to reflect first circularly polarized light of the first turning direction of the selective reflection band. The cholesteric liquid crystal 311 has a helical axis AX1 substantially parallel to the first direction A1 and has a helical pitch P11 in the first direction A1.

The cholesteric liquid crystal 312 included in the second layer 3B is configured to reflect second circularly polarized light of the second turning direction of the selective reflection band. The cholesteric liquid crystal 312 has a helical axis AX2 substantially parallel to the first direction A1 and has a helical pitch P12 in the first direction A1. The helical axis AX1 is parallel to the helical axis AX2. The helical pitch P11 is equal to the helical pitch P12.

The cholesteric liquid crystals 311 and 312 are both formed to reflect infrared rays I as the selective reflection band. The cholesteric liquid crystal 311 of the first layer 3A forms a reflective surface 321 which reflects first circularly polarized light I1 of infrared rays I. The cholesteric liquid crystal 312 of the second layer 3B forms a reflective surface 322 which reflects second circularly polarized light 12 of infrared rays I in the second layer 3B.

In the liquid crystal optical element 100 as described above, when light LTi including visible light V, ultraviolet rays U, and infrared rays I is incident, the liquid crystal layer 3 reflects light LTr including infrared rays I and transmits light LTt including visible light V and ultraviolet rays U.

The reflective surface 321 formed in the first layer 3A of the liquid crystal layer 3 reflects first circularly polarized light I1 of infrared rays I toward the optical waveguide 1. In addition, the reflective surface 322 formed in the second layer 3B of the liquid crystal layer 3 reflects second circularly polarized light 12 of infrared rays I transmitted through the first layer 3A toward the optical waveguide 1. Light LTr including first circularly polarized light I1 and second circularly polarized light 12 reflected by the liquid crystal layer 3 is guided toward the side surface F3 while being reflected by the interface between the optical waveguide 1 and the air and the interface between the second layer 3B and the first low-refractive-index layer S1.

In the modified example as described above, not only first circularly polarized light I1 but also second circularly polarized light 12 of infrared rays I can be guided, and the efficiency of light utilization can be further improved.

The liquid crystal layer 3 may be a multilayer body of three or more layers. In addition, the helical pitches of the layers constituting the liquid crystal layer 3 may be different.

### Embodiment 2

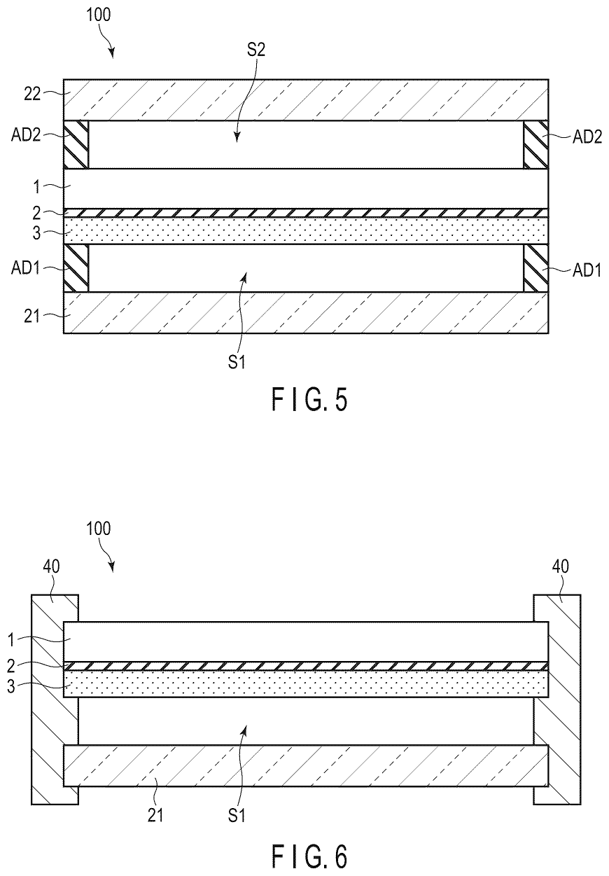

FIG. 5 is a cross-sectional view schematically illustrating a liquid crystal optical element 100 according to Embodiment 2.

Embodiment 2 illustrated in FIG. 5 is different from Embodiment 1 illustrated in FIG. 1 in that a transparent second cover member 22 opposed to an optical waveguide 1 is further provided. The stacked layer body of the optical waveguide 1, an alignment film 2, and a liquid crystal layer 3 is provided between a first cover member 21 and the second cover member 22.

The second cover member 22 is separated from the optical waveguide 1. A second low-refractive-index layer S2 is interposed between the optical waveguide 1 and the second cover member 22. The second low-refractive-index layer S2 has a refractive index lower than those of the optical waveguide 1 and the second cover member 22. The second low-refractive-index layer S2 is, for example, a vacuum (refractive index; 1.0) or an air layer (refractive index; approximately 1.0).

The second cover member 22 is a transparent flat plate, and is formed of inorganic glass or transparent resin like the first cover member 21. The thickness of the second cover member 22 is 0.1 mm to 25 mm and should preferably be 1 mm to 20 mm.

A second adhesive AD2 adheres the periphery of the second cover member 22 to the optical waveguide 1 in a state in which the second low-refractive-index layer S2 is interposed between the optical waveguide 1 and the second cover member 22. The second adhesive AD2 is formed in, for example, the shape of a continuous loop, and seals the air layer as the second low-refractive-index layer S2 on its inside.

As the second adhesive AD2, the same material as that of the above-described first adhesive AD1 can be applied.

In Embodiment 2, too, the same advantages as those of Embodiment 1, described above, are achieved. In addition, since the optical waveguide 1 is protected by the second cover member 22, the adhesion of dirt or a waterdrop to the optical waveguide 1 is suppressed and the damage to the optical waveguide 1 is suppressed. This suppresses the undesirable scattering of light due to the adhesion of dirt or a waterdrop to the optical waveguide 1 or the undesirable scattering of light due to the damage to the optical waveguide 1. Accordingly, the decrease in the efficiency of light utilization in the liquid crystal optical element 100 is suppressed.

### Embodiment 3

FIG. 6 is a cross-sectional view schematically illustrating a liquid crystal optical element 100 according to Embodiment 3.

Embodiment 3 illustrated in FIG. 6 is different from Embodiment 1 illustrated in FIG. 1 in that a support body 40 which supports a first cover member 21 is provided instead of a first adhesive AD1.

The support body 40 supports the stacked layer body of an optical waveguide 1, an alignment film 2, and a liquid crystal layer 3, and the first cover member 21. In addition, the support body 40 supports the first cover member 21 in a state in which a first low-refractive-index layer S1 is interposed between the liquid crystal layer 3 and the first cover member 21. The first low-refractive-index layer S1 is an air layer or the like.

The support body 40 is formed of metal such as aluminum, iron, or steel, resin such as hard vinyl chloride resin, wood, a composite material, or the like.

In Embodiment 3, too, the same advantages as those of Embodiment 1, described above, are achieved.

### Embodiment 4

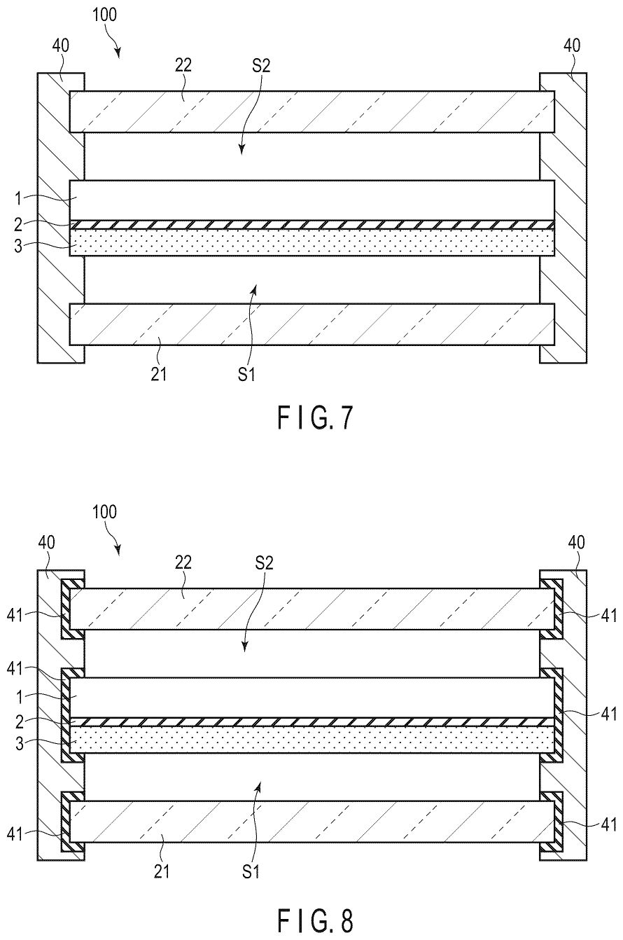

FIG. 7 is a cross-sectional view schematically illustrating a liquid crystal optical element 100 according to Embodiment 4.

Embodiment 4 illustrated in FIG. 7 is different from Embodiment 2 illustrated in FIG. 5 in that a support body 40 which supports a first cover member 21 and a second cover member 22 are provided instead of a first adhesive AD1 and a second adhesive AD2. The first cover member 21 is opposed to a liquid crystal layer 3 with a first low-refractive-index layer S1 interposed therebetween, and the second cover member 22 is opposed to an optical waveguide 1 with a second low-refractive-index layer S2 interposed therebetween.

The support body 40 supports the stacked layer body of the optical waveguide 1, an alignment film 2, and the liquid crystal layer 3, the first cover member 21, and the second cover member 22. In addition, the support body 40 supports the first cover member 21 in a state in which the first low-refractive-index layer S1 is interposed between the liquid crystal layer 3 and the first cover member 21, and supports the second cover member 22 in a state in which the second low-refractive-index layer S2 is interposed between the optical waveguide 1 and the second cover member 22. The first low-refractive-index layer S1 and the second low-refractive-index layer S2 are air layers or the like.

The material forming the support body 40 is as described in Embodiment 3.

In Embodiment 4, too, the same advantages as those of Embodiment 2, described above, are achieved.

### Embodiment 5

FIG. 8 is a cross-sectional view schematically illustrating a liquid crystal optical element 100 according to Embodiment 5.

Embodiment 5 illustrated in FIG. 8 is different from Embodiment 4 illustrated in FIG. 7 in that a cushioning member 41 is provided on a support surface of a support body 40. The cushioning member 41 is interposed between the stacked layer body of an optical waveguide 1, an alignment film 2, and a liquid crystal layer 3, and the support body 40. In addition, the cushioning member 41 is interposed between a first cover member 21 and the support body 40. Moreover, the cushioning member 41 is interposed between a second cover member 22 and the support body 40.

The cushioning member 41 is formed of a material softer than the support body 40. As the material forming the cushioning member 41, a rubber material such as silicone rubber, fluorine rubber, chloroprene rubber, nitrile rubber, or ethylene propylene rubber, a cushioning material such as polyurethane form, polystyrene foam, or foamed polypropylene, or the like can be applied.

In Embodiment 5, too, the same advantages as those of Embodiment 2, described above, are achieved. In addition, the damage due to the contact of each of the optical waveguide 1, the liquid crystal layer 3, the first cover member 21, and the second cover member 22 with the hard support body 40 is suppressed.

The cushioning member 41 described in Embodiment 5 can be applied in Embodiment 3 illustrated in FIG. 6 as well, and the cushioning member 41 may be interposed between the stacked layer body of the optical waveguide 1, the alignment film 2, and the liquid crystal layer 3, and the support body 40 and between the first cover member 21 and the support body 40.

### Embodiment 6

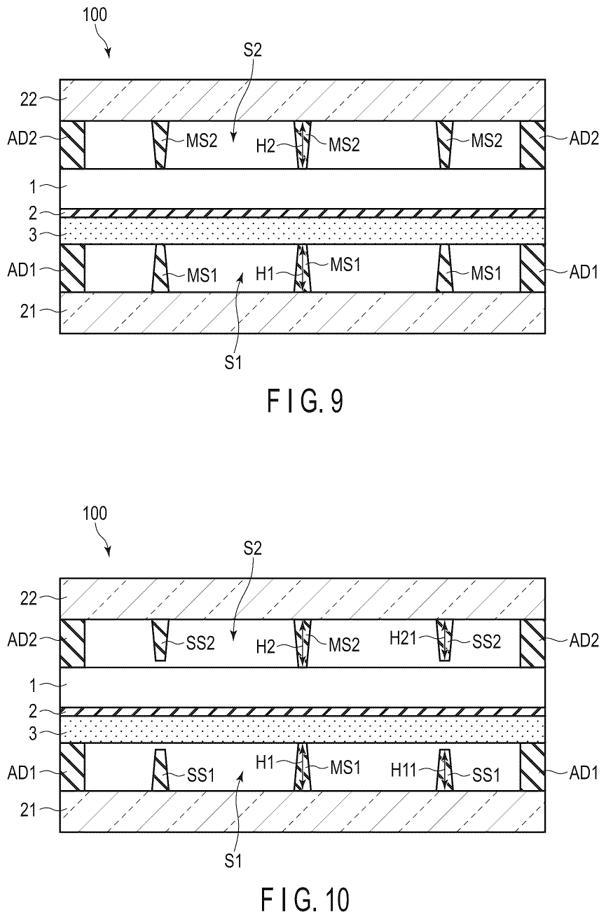

FIG. 9 is a cross-sectional view schematically illustrating a liquid crystal optical element 100 according to Embodiment 6.

Embodiment 6 illustrated in FIG. 9 is different from Embodiment 2 illustrated in FIG. 5 in that first main spacers MS1 and second main spacers MS2 are provided.

The first main spacers MS1 contact a liquid crystal layer 3 and a first cover member 21. The first main spacers MS1 are formed in the shape of columns tapering from the first cover member 21 toward the liquid crystal layer 3. The first main spacers MS1 are disposed in an inner area surrounded by a first adhesive AD1, and are each surrounded by a first low-refractive-index layer S1. In addition, the first main spacers MS1 have a substantially equal height H1, and form the first low-refractive-index layer S1 having a substantially uniform thickness between the first cover member 21 and the liquid crystal layer 3.

The second main spacers MS2 contact an optical waveguide 1 and a second cover member 22. The second main spacers MS2 are formed in the shape of columns tapering from the second cover member 22 toward the optical waveguide 1. The second main spacers MS2 are disposed in an inner area surrounded by a second adhesive AD2, and are each surrounded by a second low-refractive-index layer S2. In addition, the second main spacers MS2 have a substantially equal height H2, and form the second low-refractive-index layer S2 having a substantially uniform thickness between the second cover member 22 and the optical waveguide 1. The height H1 is, for example, equal to the height H2, but may be different from the height H2.

In the example illustrated in FIG. 9, the first main spacers MS1 and the second main spacers MS2 are disposed at positions overlapping each other, but may be disposed at positions shifted with respect to each other. In addition, the number of first main spacers MS1 is, for example, equal to the number of second main spacers MS2, but may be different from the number of second main spacers MS2. In addition, only the first main spacers MS1 or the second main spacers MS2 may be provided.

The first main spacers MS1 and the second main spacers MS2 are transparent. In order to make the first main spacers MS1 and the second main spacers MS2 difficult to visually recognize, it is desirable that they be formed of a material having a refractive index equal to those of the first cover member 21 and the second cover member 22. For example, the first main spacers MS1 and the second main spacers MS2 are formed of a transparent acrylic resin (refractive index; 1.49 to 1.53).

In Embodiment 6, too, the same advantages as those of Embodiment 2, described above, are achieved. In addition, even if a strong impact is applied to the first cover member 21 or the second cover member 22, the distance between the first cover member 21 and the liquid crystal layer 3 (thickness of the first low-refractive-index layer S1) and the distance between the second cover member 22 and the optical waveguide 1 (thickness of the second low-refractive-index layer S2) can be maintained. This suppresses the degradation in appearance due to interference caused by a change in the distances.

### Embodiment 7

FIG. 10 is a cross-sectional view schematically illustrating a liquid crystal optical element 100 according to Embodiment 7.

Embodiment 7 illustrated in FIG. 10 is different from Embodiment 6 illustrated in FIG. 9 in that some of first main spacers MS1 are replaced by first sub-spacers SS1 and some of second main spacers MS2 are replaced by second sub-spacers SS2.

The first sub-spacers SS1 are separated from a liquid crystal layer 3 and contact a first cover member 21. The first sub-spacers SS1 are formed in the shape of columns tapering from the first cover member 21 toward the liquid crystal layer 3. The first sub-spacers SS1 are disposed in an inner area surrounded by a first adhesive AD1 and are each surrounded by a first low-refractive-index layer S1. The first low-refractive-index layer S1 is interposed between the first sub-spacers SS1 and the liquid crystal layer 3. The height H11 of the first sub-spacers SS1 is smaller than the height H1 of the first main spacers MS1 (H11<H1). It is desirable that the number of first main spacers MS1 be less than the number of first sub-spacers SS1.

The second sub-spacers SS2 are separated from an optical waveguide 1 and contact a second cover member 22. The second sub-spacers SS2 are formed in the shape of columns tapering from the second cover member 22 toward the optical waveguide 1. The second sub-spacers SS2 are disposed in an inner area surrounded by a second adhesive AD2 and are each surrounded by a second low-refractive-index layer S2. The second low-refractive-index layer S2 is interposed between the second sub-spacers SS2 and the optical waveguide 1. The height H21 of the second sub-spacers SS2 is smaller than the height H2 of the second main spacers MS2 (H21<H2). It is desirable that the number of second main spacers MS2 be less than the number of second sub-spacers SS2.

In the example illustrated in FIG. 10, the first sub-spacers SS1 and the second sub-spacers SS2 are disposed at positions overlapping each other, but may be disposed at positions shifted with respect to each other. In addition, the first main spacers MS1 and the second sub-spacers SS2 may be disposed to overlap each other, or the second main spacers MS2 and the first sub-spacers SS1 may be disposed to overlap each other.

Moreover, the number of first sub-spacers SS1 is, for example, equal to the number of second sub-spacers SS2, but may be different from the number of second sub-spacers SS2. Furthermore, only the first sub-spacers SS1 or the second sub-spacers SS2 may be provided.

The first sub-spacers SS1 and the second sub-spacers SS2 are transparent and are formed of the same material as that of the first main spacers MS1 and the second main spacers MS2.

In Embodiment 7, too, the same advantages as those of Embodiment 2, described above, are achieved. In addition, the leakage or scattering of light propagating through the liquid crystal layer 3 is suppressed by reducing the number of first main spacers MS1 that contact the liquid crystal layer 3. Moreover, the leakage or scattering of light propagating through the optical waveguide 1 is suppressed by reducing the number of second main spacers MS2 that contact the optical waveguide 1. In this way, the decrease in the efficiency of light utilization in the liquid crystal optical element 100 is suppressed.

In addition, when such a strong impact as to deform the first main spacers MS1 and the first cover member 21 is applied, the first sub-spacers SS1 contact the liquid crystal layer 3, and when such a strong impact as to deform the second main spacers MS2 and the second cover member 22 is applied, the second sub-spacers SS2 contact the optical waveguide 1. In this way, the distance between the first cover member 21 and the liquid crystal layer 3 (thickness of the first low-refractive-index layer S1) and the distance between the second cover member 22 and the optical waveguide 1 (thickness of the second low-refractive-index layer S2) can be maintained. This suppresses the degradation in appearance due to interference caused by a change in the distances.

The modified example described with reference to FIG. 4 can be applied to each of Embodiments 2 to 7, described above. That is, the liquid crystal layer 3 may be the multilayer body of the first layer 3A comprising the cholesteric liquid crystal 311 and the second layer 3B comprising the cholesteric liquid crystal 312. In addition, the liquid crystal layer 3 may be a multilayer body of three or more layers.

Moreover, the support body 40 illustrated in FIG. 7 or the support body 40 with the cushioning member 41 illustrated in FIG. 8 may be applied instead of the first adhesives AD1 and the second adhesives AD2 illustrated in FIG. 9 and FIG. 10.

A photovoltaic cell device 200 will be described next as an application example of the liquid crystal optical elements 100 according to the present embodiments.

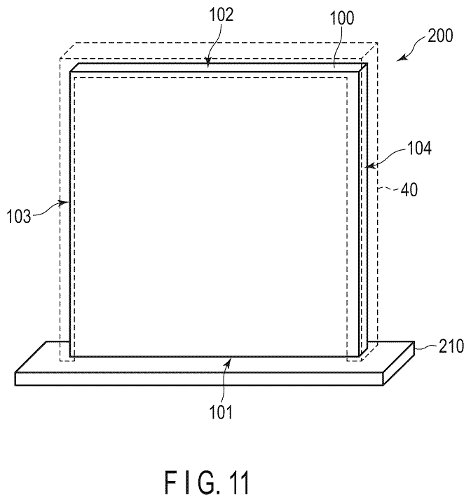

FIG. 11 is a diagram illustrating an example of the outside of the photovoltaic cell device 200.

The photovoltaic cell device 200 comprises any one of the above-described liquid crystal optical elements 100 and a power generation device 210. The power generation device 210 is provided along one side 101 of the liquid crystal optical element 100. The one side 101 of the liquid crystal optical element 100, which is opposed to the power generation device 210, is a side along the side surface F3 of the optical waveguide 1 illustrated in FIG. 1, etc. In the photovoltaic cell device 200, the liquid crystal optical element 100 functions as a lightguide element which guides light of a predetermined wavelength to the power generation device 210.

If the liquid crystal optical element 100 comprising the support body 40 described in Embodiment 3 illustrated in FIG. 6, Embodiment 4 illustrated in FIG. 7, or Embodiment 5 illustrated in FIG. 8 is applied as the liquid crystal optical element 100, the support body 40 is provided along the other three sides 102 to 104 of the liquid crystal optical element 100 as indicated by a broken line.

The power generation device 210 comprises a plurality of photovoltaic cells. The photovoltaic cells receive light and convert the energy of received light into power. That is, the photovoltaic cells generate power from received light. The types of photovoltaic cell are not particularly limited. For example, the photovoltaic cells are silicon photovoltaic cells, compound photovoltaic cells, organic photovoltaic cells, perovskite photovoltaic cells, or quantum dot photovoltaic cells. The silicon photovoltaic cells include photovoltaic cells comprising amorphous silicon, photovoltaic cells comprising polycrystalline silicon, etc.

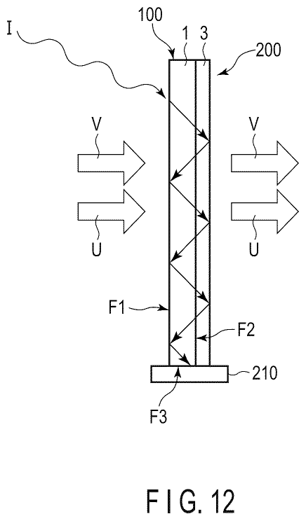

FIG. 12 is a diagram for explaining the operation of the photovoltaic cell device 200 illustrated in FIG. 11.

The first main surface F1 of the optical waveguide 1 faces outdoors. The liquid crystal layer 3 faces indoors. In FIG. 12, the illustration of the alignment film, the first cover member, etc., is omitted.

The liquid crystal layer 3 is configured to reflect infrared rays I of solar light. The liquid crystal layer 3 may be configured to reflect first circularly polarized light I1 and transmit second circularly polarized light 12 of infrared rays I as illustrated in FIG. 1, or may be configured to reflect first circularly polarized light I1 and second circularly polarized light 12 of infrared rays I as illustrated in FIG. 4. Infrared rays I reflected by the liquid crystal layer 3 propagate through the liquid crystal optical element 100 toward the side surface F3. The power generation device 210 receives infrared rays I transmitted through the side surface F3 and generates power.

Visible light V and ultraviolet rays U of solar light are transmitted through the liquid crystal optical element 100. In particular, a first component (blue component), a second component (green component), and a third component (red component), which are main components of visible light V, are transmitted through the liquid crystal optical element 100. Thus, the coloration of light transmitted through the photovoltaic cell device 200 can be suppressed. In addition, the decrease in the transmittance of visible light V in the photovoltaic cell device 200 can be suppressed.

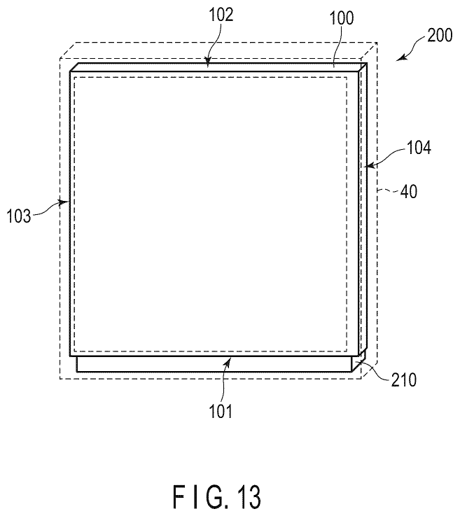

FIG. 13 is a diagram illustrating another example of the outside of the photovoltaic cell device 200.

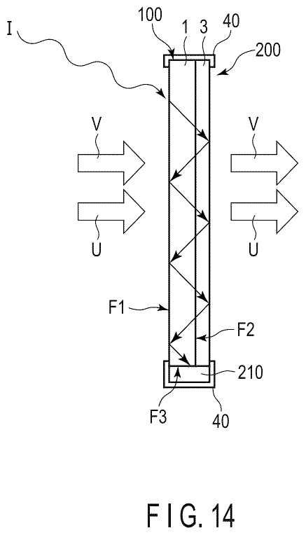

FIG. 14 is a cross-sectional view including the power generation device 210 of the photovoltaic cell device 200 illustrated in FIG. 13.

The example illustrated in FIG. 13 and FIG. 14 is different from the example illustrated in FIG. 11 and FIG. 12 in that the support body 40 is provided along the four sides 101 to 104 of the liquid crystal optical element 100. The one side 101 of the liquid crystal optical element 100 or the power generation device 210 opposed to the side surface F3 of the optical waveguide 1 is covered by the support body 40. The other three sides 102 to 104 of the liquid crystal optical element 100 are also covered by the support body 40.

In this photovoltaic cell device 200, too, the first main surface F1 of the optical waveguide 1 is disposed to face outdoors, so that the photovoltaic cell device 200 operates as described with reference to FIG. 12 and the same advantages as those described above are achieved.

As described above, according to the present embodiments, a liquid crystal optical element which can suppress the decrease in the efficiency of light utilization can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A liquid crystal optical element comprising:
an optical waveguide comprising a first main surface and a second main surface opposed to the first main surface;
an alignment film disposed on the second main surface;
a liquid crystal layer which overlaps the alignment film, which comprises cholesteric liquid crystals, and which reflects at least part of light incident through the optical waveguide toward the optical waveguide; and
a transparent first cover member opposed to the liquid crystal layer with a first low-refractive-index layer interposed between the first cover member and the liquid crystal layer, the first low-refractive-index layer having a refractive index lower than a refractive index of the liquid crystal layer.

2. The liquid crystal optical element of claim 1, wherein
the liquid crystal layer comprises a first layer and a second layer composed of the cholesteric liquid crystals, and
in the first layer and the second layer, the cholesteric liquid crystals have an equal helical pitch and turn in opposite directions.

3. The liquid crystal optical element of claim 1, further comprising a first adhesive which adheres a periphery of the first cover member to the liquid crystal layer in a state in which the first low-refractive-index layer is interposed between the liquid crystal layer and the first cover member.

4. The liquid crystal optical element of claim 3, further comprising a transparent second cover member opposed to the optical waveguide with a second low-refractive-index layer interposed between the second cover member and the optical waveguide, the second low-refractive-index layer having a refractive index lower than a refractive index of the optical waveguide.

5. The liquid crystal optical element of claim 4, further comprising a second adhesive which adheres a periphery of the second cover member to the optical waveguide in a state in which the second low-refractive-index layer is interposed between the optical waveguide and the second cover member.

6. The liquid crystal optical element of claim 1, further comprising a support body which supports the first cover member in a state in which the first low-refractive-index layer is interposed between the liquid crystal layer and the first cover member.

7. The liquid crystal optical element of claim 6, further comprising a transparent second cover member opposed to the optical waveguide with a second low-refractive-index layer interposed between the second cover member and the optical waveguide, the second low-refractive-index layer having a refractive index lower than a refractive index of the optical waveguide.

8. The liquid crystal optical element of claim 7, wherein the support body supports the second cover member in a state in which the second low-refractive-index layer is interposed between the optical waveguide and the second cover member.

9. The liquid crystal optical element of claim 8, further comprising a cushioning member which is interposed between a stacked layer body of the optical waveguide, the alignment film, and the liquid crystal layer, and the support body, between the first cover member and the support body, and between the second cover member and the support body.

10. The liquid crystal optical element of claim 1, further comprising a first main spacer which contacts the liquid crystal layer and the first cover member, and which is surrounded by the first low-refractive-index layer.

11. The liquid crystal optical element of claim 10, further comprising a first sub-spacer which is separated from the liquid crystal layer, which contacts the first cover member, and which is surrounded by the first low-refractive-index layer.

12. The liquid crystal optical element of claim 1, further comprising:
a transparent second cover member opposed to the optical waveguide with a second low-refractive-index layer interposed between the second cover member and the optical waveguide, the second low-refractive-index layer having a refractive index lower than a refractive index of the optical waveguide; and
a second main spacer which contacts the optical waveguide and the second cover member, and which is surrounded by the second low-refractive-index layer.

13. The liquid crystal optical element of claim 12, further comprising a second sub-spacer which is separated from the optical waveguide, which contacts the second cover member, and which is surrounded by the second low-refractive-index layer.
